(19) United States
(12) Patent Application Publication
(10) Pub. No.: US 2008/0100333 A1
(43) Pub. Date: May 1, 2008

(54) Impedance matching circuit of semiconductor memory device

(75) Inventors: Ki-Ho Kim, Kyoungki-do (KR); Chun-Seok Jeong, Kyoungki-do (KR)

Correspondence Address: MCDERMOTT WILL & EMERY LLP, 600 13TH STREET, N.W., WASHINGTON, DC, 20005-3096, US

(73) Assignee: HYNIX SEMICONDUCTOR INC.

(21) Appl. No.: 11/819,793

(22) Filed: Jun. 29, 2007

(30) Foreign Application Priority Data
Oct. 31, 2006 (KR) 2006-0106129

(51) Int. Cl. H03K 19/0175

(52) U.S. Cl. 326/30

(57) ABSTRACT

An impedance matching circuit reduces current consumption during ZQ calibration in the present invention. The impedance matching circuit includes a reference voltage generator, a code generator, a first pull-up resistance unit, a second pull-up resistance unit and a pull-down resistance unit. The reference voltage generator generates a reference voltage. The code generator generates a pull-up calibration code by comparing the reference voltage with a voltage at a first node and a pull-down calibration code by comparing the reference voltage with a voltage at a second node. The first pull-up resistance unit calibrates its resistance to be bigger than a reference resistance. The second pull-up resistance unit calibrates its resistance to be bigger than the reference resistance. The pull-down resistance unit calibrates its resistance to the reference resistance.

### CROSS-REFERENCE TO RELATED APPLICATIONS

The present invention claims priority of Korean patent application no. 10-2006-0106129, filed in the Korean Patent Office on Oct. 31, 2006, which is incorporated by reference in its entirety.

### BACKGROUND OF THE INVENTION

The present invention relates to an impedance matching circuit in a semiconductor memory device; more particularly, to ZQ calibration performed by the impedance matching circuit.

As an operation speed of electrical products increases, swing width of signals transmitted between semiconductor memory devices inside the electrical products decreases to minimize a delay time taken to transmit the signals. However, as the swing width decreases, signal transmission is more affected by external noises and signal reflection in an interface terminal would increase by impedance mismatching.

The impedance mismatching is caused by variation of a manufacture process, a supply voltage and an operation temperature (PVT). The impedance mismatching makes it hard to transmit data at a high speed. Because a signal outputted from a semiconductor memory device may be distorted by the impedance mismatching, malfunctions such as a set up/hold fail and misjudgment of the signal level could be caused in a corresponding semiconductor memory device receiving the distorted signal.

A semiconductor memory device includes an input circuit for receiving external signals through an input pad and an output circuit for outputting internal signals through an output pad. Particularly, a semiconductor memory device which is required to operate at a high speed includes an impedance matching circuit for matching interface impedance with a corresponding semiconductor memory device in order to prevent the above malfunctions.

Generally, in a semiconductor memory device transmitting a signal, a source termination is performed by an output circuit. In a semiconductor memory device receiving a signal, a parallel termination is performed by a termination circuit parallelly connected to the input circuit.

ZQ calibration is a process for generating pull-up and pull-down calibration codes which change as conditions of PVT change. A resistance value of the input and output circuit is calibrated by using the codes. The ZQ calibration is performed in the impedance matching circuit of the semiconductor memory device.

### SUMMARY OF THE INVENTION

Embodiments of the present invention are directed to providing an impedance matching circuit for reducing current consumption during ZQ calibration.

In accordance with an aspect of the present invention, an impedance matching circuit includes a reference voltage generator for generating a reference voltage, a code generator for generating a pull-up calibration code by comparing the reference voltage with a voltage at a first node and a pull-down calibration code by comparing the reference voltage with a voltage at a second node, a first pull-up resistance unit for supplying a supply voltage to the first node in response to the pull-up calibration code to thereby calibrate its resistance to be bigger than a reference resistance, a second pull-up resistance unit for supplying the supply voltage to the second node in response to the pull-up calibration code to thereby calibrate its resistance to be bigger than the reference resistance and a pull-down resistance unit for supplying a ground voltage to the second node in response to the pull-down calibration code to thereby calibrate its resistance to the reference resistance.

In accordance with an another aspect of the present invention, an impedance matching circuit includes a reference resistor, a pull-up resistor for calibrating its resistance to be bigger than that of the reference resistor and a reference voltage generator for generating a reference voltage whose level is controlled according to a ratio of the resistance of the reference resistor to that of the pull-up resistor.

### BRIEF DESCRIPTION OF THE DRAWINGS

FIG. 1 is a block diagram showing an impedance matching circuit in accordance with an embodiment of the present invention.

FIG. 2 is a schematic circuit diagram showing a reference voltage generator described in FIG. 1.

FIG. 3 is a graph showing a voltage level changed by the calibration.

FIG. 4 is a block diagram showing an impedance matching circuit in accordance with another embodiment of the present invention.

FIG. 5 is a schematic circuit diagram showing a reference voltage generator described in FIG. 4.

FIG. 6 is a graph showing a voltage level changed by the calibration in accordance with another embodiment.

### DESCRIPTION OF SPECIFIC EMBODIMENTS

An impedance matching circuit for reducing current consumption calibrates resistances of its pull-up resistors to be bigger than a resistance of a reference resistor. However, the impedance matching circuit generates a calibration code to be identical to a conventional code. Accordingly, while consuming less current than a conventional one, the impedance matching circuit can perform the ZQ calibration.

Hereinafter, an impedance matching circuit in accordance with the present invention will be described in detail referring to the accompanying drawings.

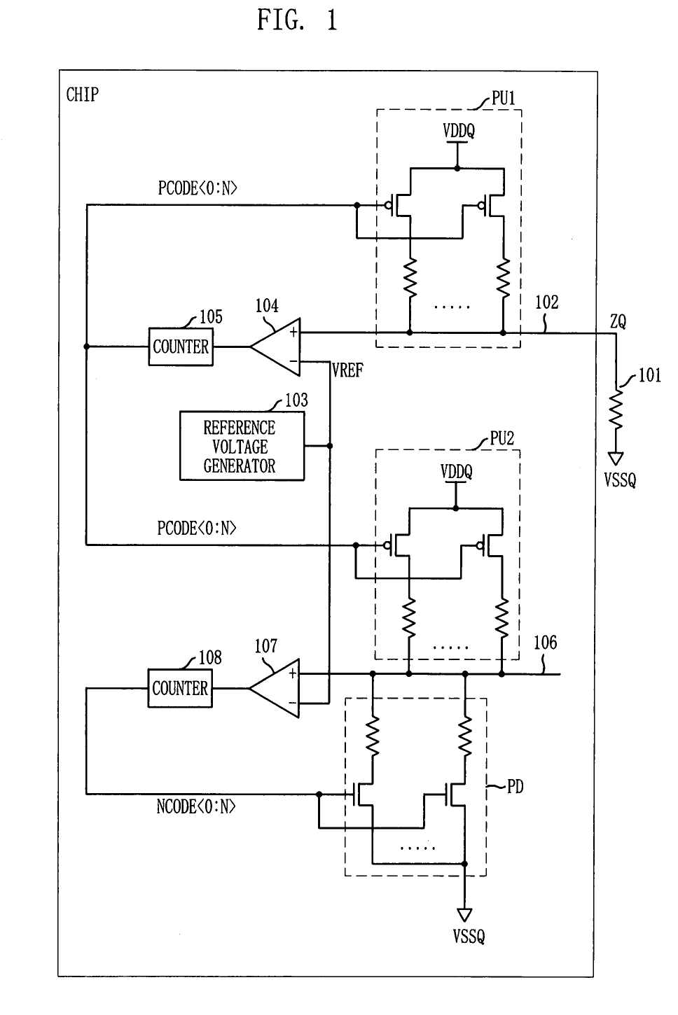

FIG. 1 is a block diagram showing an impedance matching circuit in accordance with an embodiment of present invention. The impedance matching circuit includes a first pull-up resistance unit PU1, a second pull-up resistance unit PU2, a pull-down resistance unit PD, a reference voltage generator 103, comparators 104 and 107 and counters 105 and 108.

When the first pull-up resistance unit PU1 is coupled to an external resistor 101 through a pad ZQ, a voltage is generated at a first node 102. The external resistor 101 generally has resistance of 240Ω. The comparator 104 compares the voltage at the first node 102 with a reference voltage VREF outputted from the reference voltage generator 103, to thereby generate an up/down signal UP/DOWN. The reference voltage VREF is generally set to a half of a supply voltage VDDQ/2.

The counter 105 receives the up/down signal UP/DOWN to thereby generate a binary code PCODE<0:N>. The binary code PCODE<0:N> turns on/off MOS transistors coupled in parallel in the first pull-up resistance unit PU1, to thereby calibrate resistance. The calibrated resistance of the first pull-up resistance unit PU1 has an effect on the voltage at the first node 102. Above operations are repeated. That is, calibration, i.e., pull-up calibration, is performed in the first pull-up resistance unit PU1 in order for the resistance of the first pull-up resistance unit PU1 to become identical to the resistance of the external resistor 101.

The binary code PCODE<0:N> is also inputted into the second pull-up resistance unit PU2 and determines resistance of the second pull-up resistance unit PU2. Similarly with the pull-up calibration, a pull-down calibration is performed. A voltage at a second node 106 becomes identical to the reference voltage VREF by a binary code NCODE<0:N> generated by the comparator 107 and the counter 108. The pull-down calibration is performed in order for resistance of the pull-down resistance unit PD to become identical to the resistance of the second pull-up resistance unit PU2.

The ZQ calibration includes the pull-up calibration and the pull-down calibration. The binary codes PCODE<0:N> and NCODE<0:N> resulting from the ZQ calibration are inputted to input or output circuits and calibrate its resistance to an external resistance.

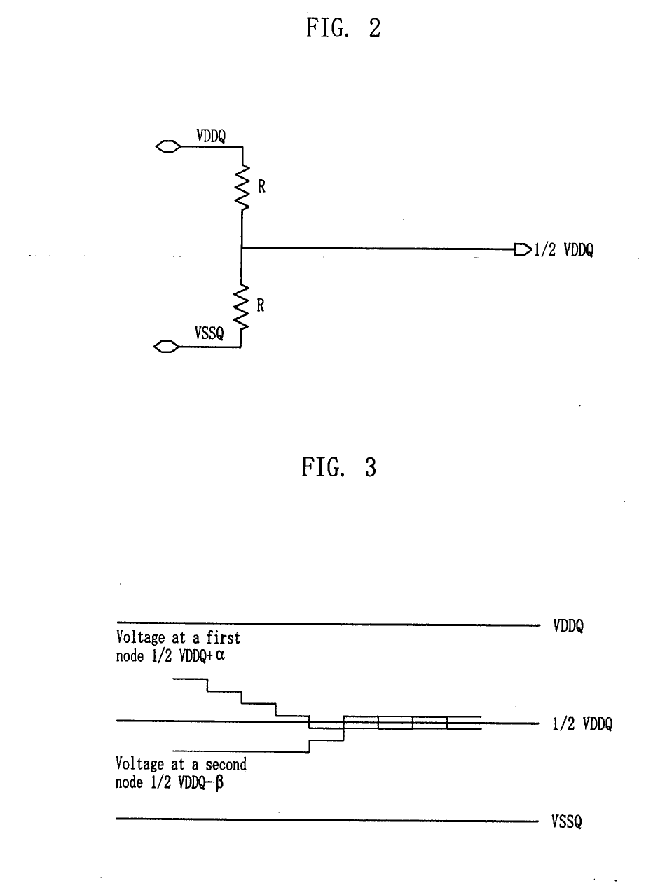

FIG. 2 is a schematic circuit diagram showing the reference voltage generator 103 described in FIG. 1.

The reference voltage generator 103 generates the reference voltage VREF and sets a target voltage. Generally, the reference voltage generator 103 outputs a reference voltage VREF having the half of the supply voltage VDDQ/2. As described in FIG. 2, the reference voltage generator 103 divides the supply voltage VDDQ with resistors to generate the reference voltage VREF.

FIG. 3 is a graph showing voltage level changed by the calibration.

As a predetermined time passes, the voltages at the first and second node 102 and 106 converge on the level of the reference voltage VREF, i.e., a target voltage. In the impedance matching circuit described in FIG. 3, the voltages at the first and second nodes 102 and 106 converse on the half of the supply voltage VDDQ/2.

In a double data rate 3 (DDR3) memory device using the ZQ calibration, three kind of ZQ calibration ZQInit, ZQCS and ZQOper are performed. The calibration ZQInit is an initial calibration operation performed first after a power up. Accordingly, it is performed in 512 cycles of a clock signal. The calibration ZQCS is performed as periodically repeated. It is performed in 256 cycles of the clock signal. The calibration ZQOper is performed in response to a command signal inputted from an external controller. It is performed in 64 cycles of the clock signal. Accordingly, in order for a semiconductor memory device to perform the ZQ calibration, much current is consumed.

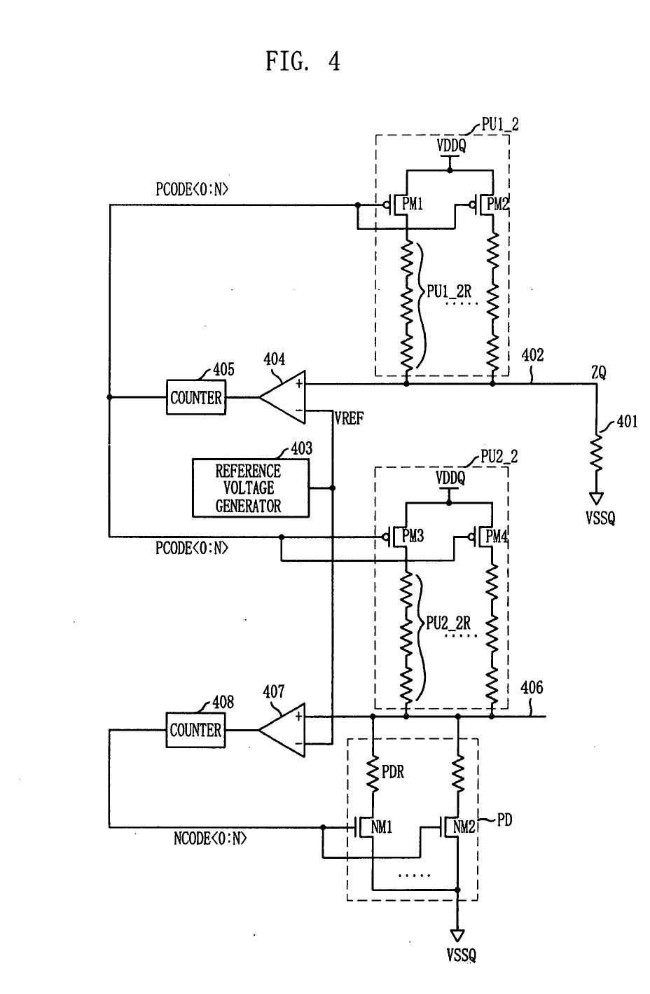

FIG. 4 is a block diagram showing an impedance matching circuit in accordance with the present invention. The impedance matching circuit includes a reference voltage generator 403, a code generator, a first pull-up resistance unit PU1_2, a second pull-up resistance unit PU2_2 and a pull-down resistance unit PD.

The reference voltage generator 403 generates the reference voltage VREF to be compared with voltages at a first node 402 and a second node 406. Through comparing processes, a pull-up calibration code PCODE<0:N> and a pull-down calibration code NCODE<0:N> are generated. The reference voltage VREF is a target voltage on which the voltages at the first node 402 and the second node 406 converge during a calibration operation.

The code generator includes counters 405 and 408 and comparators 404 and 407. The first comparator 404 generates an up/down signal by comparing the reference voltage VREF and the voltage at the first node 402. The pull-up counter 405 outputs the pull-up calibration code PCODE<0:N> in response to the up/down signal of the first comparator 404. The second comparator 407 generates an up/down signal by comparing the reference voltage VREF and the voltage at the second node 406. The pull-down counter 408 outputs the pull-down calibration code NCODE<0:N> in response to the up/down signal of the second comparator 407.

The first pull-up resistance unit PU1_2 supplies a supply voltage VDDQ to the first node 402 in response to the pull-up calibration code PCODE<0:N>. A resistance of the first pull-up resistance unit PU1_2 is calibrated to be bigger than a resistance of a reference resistor 401. That is, the resistance of the first pull-up resistance unit PU1_2 becomes bigger than the resistance of the reference resistor 401 in accordance with an embodiment of the present invention.

The reference voltage VREF should be less than a half of the supply voltage VDDQ/2 in order that the resistance of the first pull-up resistance unit PU1_2 is calibrated to be bigger than the resistance of the reference resistor 401. The resistance of the first pull-up resistance unit PUI_2 is changed during the calibration operation, in order that the voltage at the first node 402 becomes identical to the reference voltage VREF. Accordingly, if the reference voltage VREF is less than 1/N times the supply voltage, i.e., VDDQ*1/N, 1/N times the supply voltage VDDQ*1/N is loaded on the reference resistor 401 and (N−1)/N times the supply voltage VDDQ*(N−1)/N is loaded on the first pull-up resistance unit PU1_2. Because the (N−1)/N times the supply voltage VDDQ*(N−1)N is loaded on the first pull-up resistance unit PU1_2, the resistance of the first pull-up resistance unit PU1_2 becomes bigger than N−1 times the resistance of the reference resistor 401.

For example, if the reference voltage VREF is a quarter of the supply voltage VDDQ*¼, the quarter of the supply voltage VDDQ*¼ is loaded on the reference resistor 401 and ¾ times the supply voltage VDDQ*¾ is loaded on the first pull-up resistance unit PU1_2. The resistance of the first pull-up resistance unit PU1_2 becomes bigger than 3 times the reference resistor 401.

When the resistance of the first pull-up resistance unit PU1_2 is calibrated to be bigger than the resistance of the reference resistor 401, current consumption of the impedance matching circuit can be reduced. On the occasion that the reference resistor 401, i.e., an external resistor, has a resistance of 240Ω and the supply voltage VDDQ has a voltage of 1.5 Volt, a current of 3.125 mA, i.e., 1.5/480 mA, flows at the first node 102 in a conventional impedance matching circuit. However, the first pull-up resistance unit PU1_2 of the present invention has 3 times the resistance of the reference resistor. A current of 1.56 mA, i.e., 1.5/960 mA, flows at the first node 402 and current consumption is reduced by half.

The first pull-up resistance unit PU1_2 includes plurality of resistors and transistors. The plurality of resistors are connected in parallel between the first node 402 and the supply voltage VDDQ. The transistors PM1 and PM2 turn on or off the plurality of resistors under the control of the pull-up calibration code PCODE<0:N>.

The ZQ calibration represents an operation to generate the calibration codes PCODE<0:N> and NCODE<0:N> which control an interface resistance of the semiconductor memory device. Accordingly, though the resistance of the first pull-up resistance unit PU1_2 is calibrated to N−1 times the resistance of the reference resistor 401, the calibration codes NCODE<0:N> should be outputted to be identical to conventional codes. Accordingly, a resistance of each resistor such as a resistor PU1_2R in the first pull-up resistance unit PU1_2 is set to N−1 times a resistance of each resistor such as a resistor PDR in parallel connected in the pull-down resistance unit PD.

The second pull-up resistance unit PU2_2 supplies the supply voltage VDDQ to the second-node 406 in response to the pull-up calibration code PCODE<0:N> and calibrates its resistance to the resistance of the first pull-up resistance unit PU1_2. The second pull-up resistance unit PU2_2 operates the same as the first pull-up resistance unit PU1_2 does except that the second pull-up resistance unit PU2_2 supplies the second node 406.

Accordingly, the second pull-up resistance unit PU2_2 has an identical structure with the first pull-up resistance unit PU1_2. The second pull-up resistance unit PU2_2 includes plurality of resistors and transistors. The plurality of resistors are connected in parallel between the second node 406 and the supply voltage VDDQ. The transistors PM3 and PM4 turn on or off the plurality of resistors under the control of the pull-up calibration code PCODE<0:N>. Because the resistance of the second pull-up resistance unit PU2_2 is calibrated to be bigger than the resistance of the reference resistor 401, current flowing at the second node 406 is also reduced.

The pull-down resistance unit PD supplies a ground voltage VSSQ to the second node 406 in response to the pull-down calibration code NCODE<0:N>. The pull-down resistance unit PD includes plurality of resistors and transistors. The plurality of resistors are connected in parallel between the second node 406 and the ground voltage VSSQ. The transistors NM1 and NM2 turn on or off the plurality of resistors under the control of the pull-down calibration code NCODE<0:N>.

Because the resistance of each resistor such as the resistor PDR in the pull-down resistance unit PD is 1/(N−1) times the resistance of each resistor such as a resistor PU2_2R in the second pull-up resistance unit PU2_2, a resistance of the pull-down resistance unit PD is calibrated to the resistance of the reference resistor 401. Accordingly, the pull-down calibration code NCODE<0:N> is outputted to be identical to a conventional code.

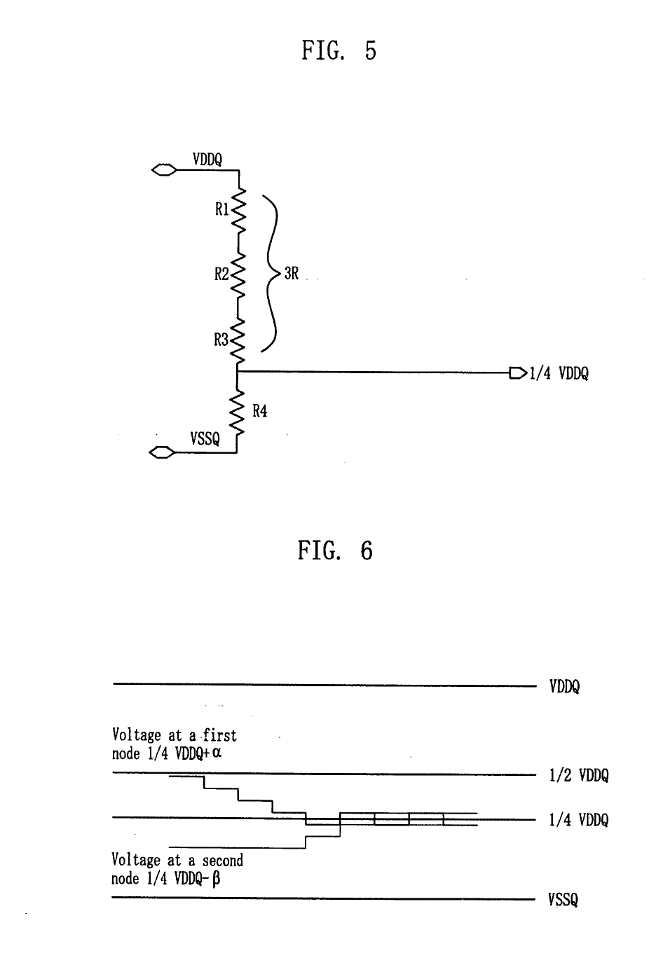

FIG. 5 is a schematic circuit diagram showing the reference voltage generator 403 described in FIG. 4.

The reference voltage generator 403 generates the reference voltage VREF by dividing the supply voltage VDDQ and the ground voltage VSSQ. The reference voltage generator 403 includes a plurality of resistors in series. In accordance with one embodiment, the reference voltage generator 403 for generating the reference voltage VREF having the quarter of the supply voltage VDDQ*¼ is described. Accordingly, a resistance of upper resistors R1 to R3 is bigger than 3 times that of lower resistor R4.

FIG. 6 is a graph showing voltage level changed by the calibration in accordance with the present invention.

The voltages at the first node 402 and the second node 406 converge on the reference voltage VREF, i.e., the quarter of the supply voltage VDDQ*¼, during the calibration. When the voltages at the first node 402 and the second node 406 becomes the quarter of the supply voltage VDDQ*¼, the resistance of the first and the second pull-up resistance units PU1_2 and PU2_2 will be calibrated to 3 times the resistance of reference resistor 401 and the resistance of the pull-down resistance unit PD will be calibrated to the resistance of the reference resistor 401.

While the present invention has been described with respect to the particular embodiments, it will be apparent to those skilled in the art that various changes and modifications may be made without departing from the spirit and scope of the invention as defined in the following claims.

What is claimed is:

1. An impedance matching circuit of a semiconductor memory device, comprising:
a reference voltage generator for generating a reference voltage;
a code generator for generating a pull-up calibration code by comparing the reference voltage with a voltage at a first node and a pull-down calibration code by comparing the reference voltage with a voltage at a second node;
a first pull-up resistance unit for supplying a supply voltage to the first node in response to the pull-up calibration code to thereby calibrate its resistance to be bigger than a reference resistance;
a second pull-up resistance unit for supplying the supply voltage to the second node in response to the pull-up calibration code to thereby calibrate its resistance to be bigger than the reference resistance; and
a pull-down resistance unit for supplying a ground voltage to the second node in response to the pull-down calibration code to thereby calibrate its resistance to the reference resistance.

2. The impedance matching circuit of claim 1, wherein the reference voltage is less than the half of the supply voltage.

3. The impedance matching circuit of claim 2, wherein the resistance of the first and the second pull-up resistance units is calibrated to N−1 times the reference resistance when the reference voltage is 1/N times the supply voltage.

4. The impedance matching circuit of claim 2, wherein the reference voltage generator generates the reference voltage by dividing the supply voltage.

5. The impedance matching circuit of claim 4, wherein the reference voltage generator includes a plurality of resistors connected in series between a supply voltage terminal and a ground voltage terminal.

6. The impedance matching circuit of claim 3, wherein the pull-down resistance unit includes:
a plurality of pull-down resistors connected in parallel between the second node and a ground voltage terminal; and
a plurality of transistors connected to the plurality of pull-down resistors and turned on or off under the control of the pull-down calibration code.

7. The impedance matching circuit of claim 6, wherein the first pull-up resistance unit includes:
a plurality of first pull-up resistors connected in parallel between the first node and a supply voltage terminal; and
a plurality of transistors connected to the plurality of first pull-up resistors and turned on of off under the control of the pull-up calibration code.

8. The impedance matching circuit of claim 7, wherein the resistance of the plurality of first pull-up resistors is N−1 times the resistance of the plurality of pull down resistors.

9. The impedance matching circuit of claim 6, wherein the second pull-up resistance unit includes:
a plurality of second pull-up resistors connected in parallel between the second node and a supply voltage terminal; and
a plurality of transistors connected to the plurality of second pull-up resistors and turned on or off under the control of the pull-up calibration code.

10. The impedance matching circuit of claim 9, wherein the resistance of the plurality of second pull-up resistors is N−1 times the resistance of the plurality of pull down resistors.

11. The impedance matching circuit of claim 1, the code generator includes:
a first comparator for generating a first up/down signal by comparing the reference voltage and the voltage at the first node;
a pull-up counter for generating the pull-up calibration code in response to the first up/down signal;
a second comparator for generating a second up/down signal by comparing the reference voltage and the voltage at the second node; and
a pull-down counter for generating the pull-down calibration code in response to the second up/down signal.

12. An impedance matching circuit of a semiconductor memory device, comprising:
a reference resistor;
a pull-up resistor for calibrating its resistance to be bigger than that of the reference resistor; and
a reference voltage generator for generating a reference voltage whose level is controlled according to a ratio of the resistance of the reference resistor to that of the pull-up resistor.

13. The impedance matching circuit of claim 12, wherein the reference voltage generator generates the reference voltage by dividing a supply voltage according to the ratio of the resistance of the reference resistor to that of the pull-up resistor.
